(19) United States
(12) Patent Application Publication
(10) Pub. No.: US 2004/0268209 A1
(43) Pub. Date: Dec. 30, 2004

(54) Concatenated iterative forward error correction codes

(76) Inventors: Apoorv Srivastava, Franklin Park, NJ (US); Avinash Velingker, Orefield, PA (US)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 10/829,920

(22) Filed: Apr. 22, 2004

Related U.S. Application Data
(60) Provisional application No. 60/464,544, filed on Apr. 22, 2003.

(51) Int. Cl. H03M 13/00

(52) U.S. Cl. 714/782

(57) ABSTRACT

Techniques that may be used in communication systems include encoding a stream of data using concatenated BCH codes, communicating the encoded data over a transmission medium, and decoding the encoded data using the BCH codes. The overhead of the concatenated BCH codes may substantially match the overhead of the Reed-Solomon RS(255/239) code. Examples of pairs of concatenated BCH codes include [BCH(2040,1952), BCH(3904, 3832)] and [BCH(2040, 1941), BCH(3882, 3834)].

### RELATED APPLICATIONS

This application claims priority from U.S. Provisional patent Application No. 60/464,544 filed Apr. 22, 2003.

### TECHNICAL FIELD

This disclosure relates to concatenated iterative forward error correction coding.

### BACKGROUND

Forward error correction (FEC) may be used in communications systems, such as terrestrial and satellite radio systems, to address signal waveform and spectrum distortions and to provide high quality communications over the radio frequency (RF) propagation channel. Examples of forward error correction techniques for communications systems include convolutional codes and block codes such as Reed-Solomon (RS) or Bose-Chaudhuri-Hocquenghem (BCH) codes.

A BCH code is an example of a code which can be used for correcting error bits in input data and which can help reduce the effects of noise interference. A binary BCH code is a class of error detecting and error correcting codes having a code word length of N=2^{m}−1 where each symbol has m bits. BCH encoding involves adding a set of additional unique bits to a message where the number of bits depends on the error detection and correction capability required. For example, in a BCH code (x, y), the total number of bits is x, which includes y data bits. The code can use a total of (x-y) parity bits. In general, there is a trade-off between overhead, on the one hand, and error detection and correction on the other.

### SUMMARY

The invention relates to techniques for performing error correction including encoding a stream of data using concatenated BCH codes, communicating the encoded data over a transmission medium, and decoding the encoded data using the BCH codes.

The concatenated codes may include a pair of BCH codes and may result in an overhead that substantially matches the overhead of the Reed-Solomon RS(255/239) code.

In one embodiment, a first one of the BCH codes is a BCH(2040,1952) code, which is a shortened version of BCH(2047,1959), and the second code is a BCH(3904,3832) code, which is a shortened version of BCH(4095,4023). Either of the codes may be used as an inner or an outer code. Preferably, eight bits of the BCH(3904,3832) code are reserved.

In another embodiment, a first one of the codes is a BCH(2040, 1941) code, which is a shortened version of a BCH(2047, 1948) code, and the second code is a BCH(3882, 3834) code, which is a shortened version of a BCH(4095,4047) code. Either of the codes may be used as the inner or outer code. Preferably, ten bits of the BCH(3882,3834) code are reserved.

The foregoing techniques may be used in systems that conform to International Telecommunication Union (ITU) standard G.709. At the same time, use of the concatenated BCH codes may achieve a higher coding gain.

Other features and advantages will be readily apparent from the following detailed description, the accompanying drawings and the claims.

### BRIEF DESCRIPTION OF THE DRAWINGS

FIG. 1 is a block diagram of a communication system that uses a first pair of concatenated BCH codes.

FIG. 5 is a block diagram of a communication system that uses a second pair of concatenated BCH codes.

FIG. 4 is a block diagram illustrating a system that uses two iterations of the first pair of BCH codes in the decoder.

FIG. 2 is a table of illustrating an example of inner code minimal polynomials for BCH(2040,1952).

FIG. 3 is a table of illustrating an example of outer code minimal polynomials for BCH(3904, 3832).

### DETAILED DESCRIPTION

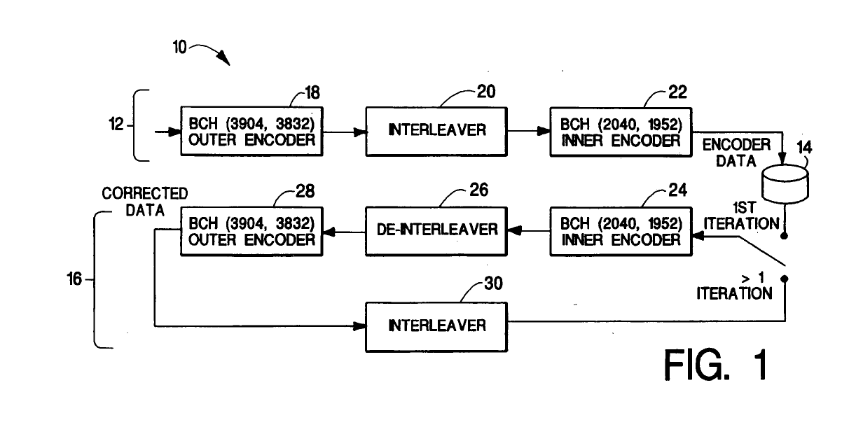

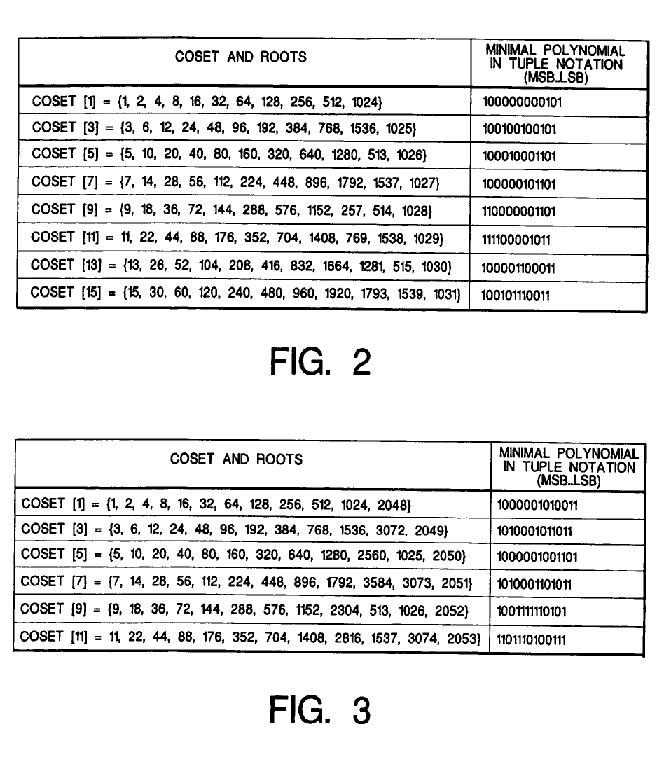

As shown in FIG. 1, a communications system 10 includes a transmitter 12, a transmission medium 14 and a receiver 16. Encoded data may be transmitted from the transmitter to the receiver over the transmission medium which may include, for example, free space, fiber optics or wireless media. Pairs of concatenated BCH codes are used for encoding and decoding the data with the result that the overhead substantially matches the overhead of the Reed-Solomon RS(255/239) code.

The transmitter 12 includes an outer encoder 18 whose output is coupled to an interleaver 20. One function of the interleaver is to reduce the impact of burst errors. The output of the interleaver is coupled to an inner encoder 22.

At the receiver, the encoded data is passed to an inner decoder 24 whose output is coupled to a deinterleaver 26. The output of the deinterleaver is coupled to an outer decoder 28. The decoding may be performed in an interative manner using one or more iterations through the receiver loop. In general, the higher the number of iterations, the higher the error correction capability of the concatenated codes.

The transmitter and receiver may be implemented in hardware or software. When high speeds (e.g., speeds of ten gigabits or higher) are to be used, it may be desirable to implement the system in hardware, for example, using one or more integrated chips. When the receiver is implemented in hardware, an inner decoder, deinterleaver and outer decoder may be provided for each iteration in the receiver loop. For implementations using multiple iterations, the output from the outer decoder of a particular iteration may be passed through an interleaver 30 before being passed to the inner decoder in the next iteration, and so on. The corrected (i.e., decoded) data is obtained from the outer decoder in the last iteration.

In the implementation of FIG. 1, the outer and inner codes, respectively, of the transmitter are BCH(3904, 3832) and BCH(2040,1952).

The outer code, BCH(3904, 3832), is a narrow sense (i.e, first root is β¹) primitive and is shortened by 191 bits from the BCH(4095, 4023) code. It is capable of correcting 6 bit-errors. In one implementation, eight data bits (i.e., one byte of data bits) are reserved in the outer code. Thus, the overhead of the outer code is 3904/3824=244/239.

The inner code, BCH(2040, 1952) is shortened by seven bits from the BCH(2047, 1959) code and is capable of correcting 8 bit-errors. The overhead of the inner code is 2040/1952=255/244.

Therefore, the overhead of the concatenated pair of codes BCH is 255/244*244/239=255/239=1.0669 which substantially matches the overhead of the RS(255/239) code. Conveniently, the number of parity bits in each of the BCH codes is a multiple of eight.

In the implementation of FIG. 1, the same BCH codes are used for the outer and inner BCH codes, respectively, in the receiver. Thus, the BCH(2040, 1952) code is used for the receiver's inner decoder and the BCH(3904, 3832) code is used for the receiver's outer decoder.

The inner and outer encoders in the transmitter include generator polynomials. An example of a generator polynomial for the inner code, BCH(2040, 1952), in tuple notation from most significant bit (MSB) to least significant bit (LSB) is: 10 000 011 011 000 000 000 100 111 100 101 000 100 001 111 110 001 000 100 110 101 010 100 01 010 110 110 111 010 011. The degree of the generator polynomial is eighty-eight, and the weight of the polynomial (non-zero elements) is thirty-nine, in other words, there are thirty-nine taps in the encoder circuit. The field generator polynomial for the 2K code is: octal 4005=x¹¹+x²+1.

An example of a generator polynomial for the outer code in tuple notation from most significant bit (MSB) to least significant bit (LSB) is: 1 100 001 011 111 101 010 011 100 110 110 000 101 111 110 110 001 011 101 101 110 011 010 000 101. The degree of the generator polynomial is severnty-two. The weight of the polynomial (non-zero elements) is forty-one. The field generator polynomial for the 4K code is: octal 10123=x¹²+x⁶+x⁴+x+1.

The inner and outer decoders in the receiver use minimal polynomials to generate the syndromes. Examples of the minimal polynomials for the inner and the outer codes are provided in the tables of FIGS. 2 and 3, respectively.

FIG. 4 illustrates a system that uses the concatenated codes, BCH(3904, 3832) and BCH(2040,1952), in which the receiver employs two decoding iterations. In particular, the first decoding iteration includes the inner decoder 34, the deinterleaver 36 and the outer decoder 38. The second iteration includes the inner decoder 44, the deinterleaver 46 and the outer decoder 48. The output from the first outer decoder 38 is passed to the interleaver 30 whose output is provided to the second inner decoder 44. The corrected payload appears as the output from the second outer decoder 48. Although FIG. 4 illustrates a system in which the receiver uses two decoding iterations, fewer or more iterations may be used in other systems.

In alternative implementations, the inner and outer BCH codes may be reversed in both the transmitter and receiver. In that case, the BCH(2040, 1952) code would be used for the transmitter's outer encoder and the receiver's outer decoder. The BCH (3904, 3832) code would be used for the transmitter's inner encoder and the receiver's inner decoder.

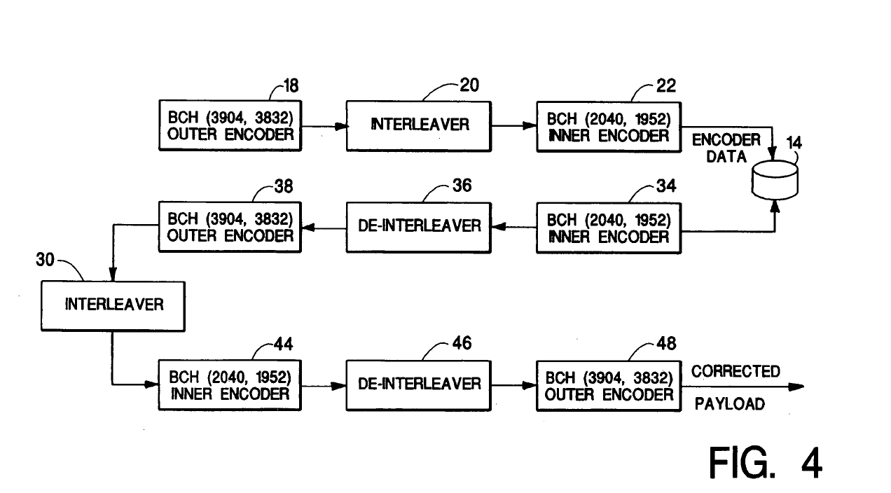

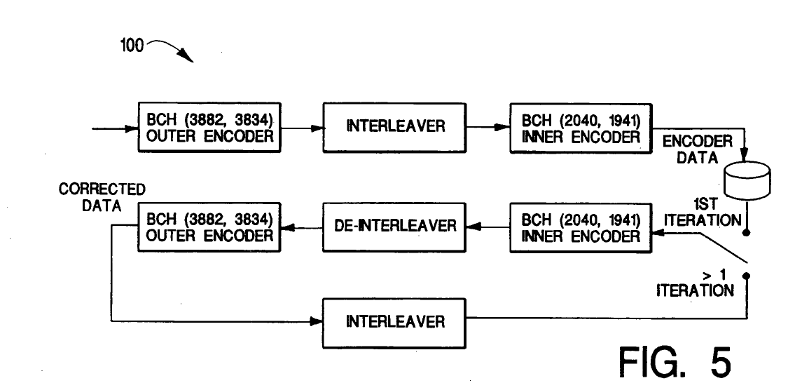

As shown in FIG. 5, a different pair of concatenated BCH codes may be used in other implementations. The system 100 may be similar to the system 10 of FIG. 1 except that the BCH(2040, 1941) code is used for the inner encoder and inner decoder, and the BCH(3882, 3834) code is used for the outer encoder and outer decoder. The BCH(2040, 1941) code is shortened by seven bits from the BCH(2047, 1948) code. Similarly, the BCH(3882, 3834) code is shortened by two hundred and thirteen bits from the BCH(4095, 4047) code. In one implementation, ten data bits are reserved in the outer code. Thus, the overhead of the concatenated codes is 2040/1941*3882/3824=1.0668, which substantially matches the overhead of the RS(255/239) code. The implementation of FIG. 5 also may include one or more decoding iterations.

In alternative implementations, the inner and outer BCH codes may be reversed in both the transmitter and receiver. In that case, the BCH(2040, 1941) code would be used for the transmitter's outer encoder and the receiver's outer decoder. The BCH (3882, 3834) code would be used for the transmitter's inner encoder and the receiver's inner decoder.

It is convenient to perform the foregoing forward error correction techniques just prior to transmission, for example, after encrypting and framing the data. In some cases other processing steps, such as scrambling, may be performed after the forward error correction but before the transmission.

Various implementations of the foregoing systems and techniques can be realized in digital electronic circuitry, integrated circuitry, specially designed ASICs (application specific integrated circuits), computer hardware, firmware, software or combinations of them. The implementations may include one or more computer programs that are executable or interpretable on a programmable system including at least one programmable processor, which may be special or general purpose, coupled to receive data and instructions from, and to transmit data and instructions to, a storage system, at least one input device, and at least one output device.

The computer programs (also known as programs, software, software applications or code) may include machine instructions for a programmable processor, and may be implemented in a high-level procedural or object-oriented programming language, or in assembly/machine language. As used herein, the term “machine-readable medium” refers to any computer program product, apparatus or device (e.g., magnetic discs, optical disks, memory, programmable logic devices (PLDs)) used to provide machine instructions or data to a programmable processor, including a machine-readable medium that receives machine instructions as a machine-readable signal. The term “machine-readable signal” refers to any signal used to provide machine instructions or data to a programmable processor.

Other implementations are within the scope of the claims.

What is claimed is:

1. A system comprising:
a transmitter to encode a stream of data using concatenated BCH codes, wherein the overhead of the concatenated BCH codes substantially matches an overhead of a RS(255/239) code;
a transmission medium to communicate the encoded data to a receiver; and
a receiver to decode the encoded data using the concatenated BCH codes.

2. A method comprising:
encoding a stream of data using concatenated BCH codes, wherein a first one of the codes is a BCH(2040,1952) code, and a second one of the codes is a BCH(3904,3832) code;
communicating the encoded data over a transmission medium; and
decoding the encoded data using the concatenated BCH codes.

3. The method of claim 2 wherein the first BCH code is a shortened version of a BCH(2047,1959) code, and the second code is a shortened version of a BCH(4095,4023) code.

4. The method of claim 3 wherein eight bits of the BCH(3904,3832) code are reserved.

5. The method of claim 2 wherein the first BCH code serves as an inner code and the second BCH code serves as an outer code.

6. A method comprising:
encoding a stream of data using concatenated BCH codes, wherein a first one of the codes is a BCH(2040, 1941) code, and a second one of the codes is a BCH(3882, 3834) code;
communicating the encoded data over a transmission medium; and
decoding the encoded data using the concatenated BCH codes.

7. The method of claim 6 wherein the first code is a shortened version of a BCH(2047, 1948) code, and the second code is a shortened version of a BCH(4095,4047) code.

8. The method of claim 7 wherein ten bits of the BCH(3882,3834) code are reserved.

9. The method of claim 6 wherein the first BCH code serves as an inner code and the second BCH code serves as an outer code.

10. A method comprising:
encoding a stream of data using concatenated BCH codes, wherein the overhead of the concatenated BCH codes substantially matches an overhead of a RS(255/239) code;
communicating the encoded data over a transmission medium; and
decoding the encoded data using the concatenated BCH codes.

11. An apparatus to transmit a stream of data comprising:
a BCH outer encoder and a BCH inner encoder; and
an interleaver coupled between the outer and inner encoders,
wherein a first one of the BCH encoders uses a BCH(2040,1952) code, and the second encoder uses a BCH(3904,3832) code.

12. The apparatus of claim 11 wherein the BCH(2040,1952) code is a shortened version of a BCH(2047,1959) code, and the BCH(3904,3832) code is a shortened version of a BCH(4095,4023) code.

13. The apparatus of claim 12 wherein eight bits of the BCH(3904,3832) code are reserved.

14. The apparatus of claim 11 wherein the inner encoder uses the BCH(2040,1952) code, and the outer encoder uses the BCH(3904,3832) code.

15. An apparatus to transmit a stream of data comprising:
A BCH outer encoder and a BCH inner encoder; and
an interleaver coupled between the outer and inner encoders,
wherein a first one of the encoders uses a BCH(2040, 1941) code, and the second encoder uses a BCH(3882, 3834) code.

16. The apparatus of claim 15 wherein the BCH(2040, 1941) code is a shortened version of a BCH(2047, 1948) code, and the BCH(3882, 3834) code is a shortened version of a BCH(4095,4047) code.

17. The apparatus of claim 16 wherein ten bits of the BCH(3882,3834) code are reserved.

18. The apparatus of claim 15 wherein the inner decoder uses the BCH(2040, 1941) code, and the outer decoder uses the BCH(3882, 3834) code.

19. An apparatus to receive a stream of data comprising:
a BCH outer decoder and a BCH inner decoder; and
an deinterleaver coupled between the outer and inner decoders,
wherein a first one of the BCH decoders uses a BCH(2040,1952) code, and the second decoder uses a BCH(3904,3832) code.

20. The apparatus of claim 19 wherein the BCH(2040,1952) code is a shortened version of a BCH(2047,1959) code, and the BCH(3904,3832) code is a shortened version of a BCH(4095,4023) code.

21. The apparatus of claim 20 wherein eight bits of the BCH(3904,3832) code are reserved.

22. The apparatus of claim 19 wherein the inner decoder uses the BCH(2040, 1952) code, and the outer decoder uses the BCH(3904, 3832) code.

23. An apparatus to receive a stream of data comprising:
A BCH outer decoder and a BCH inner decoder; and
an deinterleaver coupled between the outer and inner decoders,
wherein a first one of the decoders uses a BCH(2040, 1941) code, and the second decoder uses a BCH(3882, 3834) code.

24. The apparatus of claim 23 wherein the BCH(2040, 1941) code is a shortened version of a BCH(2047, 1948) code, and the BCH(3882, 3834) code is a shortened version of a BCH(4095,4047) code.

25. The apparatus of claim 24 wherein ten bits of the BCH(3882,3834) code are reserved.

26. The apparatus of claim 23 wherein the inner decoder uses the BCH(2040, 1941) code, and the outer decoder uses the BCH(3882, 3834) code.

27. A system comprising:
a transmitter to encode a stream of data using concatenated BCH codes, wherein a first one of the codes is a BCH(2040,1952) code, and a second one of the codes is a BCH(3904,3832) code;
a transmission medium to communicate the encoded data to a receiver; and
a receiver to decode the encoded data using the concatenated BCH codes.

28. The system of claim 27 wherein:
the transmitter comprises a BCH outer encoder, a BCH inner encoder and an interleaver coupled between the outer and inner encoders,
the receiver comprises a BCH outer decoder, a BCH inner decoder and a deinterleaver coupled between the outer and inner decoders, and
a first one of the encoders and a first one of the decoders use the BCH(2040,1952) code, and the second encoder and the second decoder use the BCH(3904,3832) code.

29. The system of claim 28 wherein the BCH(2040,1952) code is a shortened version of a BCH(2047,1959) code, and the BCH(3904,3832) code is a shortened version of a BCH(4095,4023) code.

30. The system of claim 29 wherein eight bits of the BCH(3904,3832) code are reserved.

31. The system of claim 28 wherein the inner encoder and inner decoder use the BCH(2040,1952) code, and the outer encoder and outer decoder use the BCH(3904,3832) code.

32. A system comprising:
a transmitter to encode a stream of data using concatenated BCH codes, wherein a first one of the codes is a BCH(2040, 1941) code, and a second one of the codes is a BCH(3882, 3834) code;
a transmission medium to communicate the encoded data to a receiver; and
a receiver to decode the encoded data using the concatenated BCH codes.

33. The system of claim 32 wherein:
the transmitter comprises a BCH outer encoder, a BCH inner encoder and an interleaver coupled between the outer and inner encoders,
the receiver comprises a BCH outer decoder, a BCH inner decoder and a deinterleaver coupled between the outer and inner decoders, and
a first one of the encoders and a first one of the decoders use the BCH(2040,1941) code, and the second encoder and the second decoder use the BCH(3882, 3834) code.

34. The system of claim 33 wherein the BCH(2040, 1941) code is a shortened version of a BCH(2047, 1948) code, and the BCH(3882, 3834) code is a shortened version of a BCH(4095,4047) code.

35. The system of claim 34 wherein ten bits of the BCH(3882,3834) code are reserved.

36. The system of claim 34 wherein the inner encoder and inner decoder use the BCH(2040, 1941) code, and the outer encoder and outer decoder use the BCH(3882, 3834) code.

37. A system comprising:
a transmitter to encode a stream of data using concatenated BCH codes, wherein the overhead of the concatenated BCH codes substantially matches an overhead of a RS(255/239) code;
a transmission medium to communicate the encoded data to a receiver; and
a receiver to decode the encoded data using the concatenated BCH codes.
